(19) United States
(12) Patent Application Publication
(10) Pub. No.: US 2011/0180122 A1
(43) Pub. Date: Jul. 28, 2011

(54) FLOATING GRID MODULE DESIGN FOR THIN FILM SILICON SOLAR CELLS

(75) Inventors: David Tanner, San Jose, CA (US); Hien-minh Huu Le, San Jose, CA (US); Tzay-fa Su, San Jose, CA (US); Dapeng Wang, Santa Clara, CA (US)

(73) Assignee: APPLIED MATERIALS, INC., Santa Clara, CA (US)

(21) Appl. No.: 12/694,113

(22) Filed: Jan. 26, 2010

(51) Int. Cl. H01L 31/042; H01L 31/18

(52) U.S. Cl. 136/244; 438/73; 257/E31.052

(57) ABSTRACT

A photovoltaic device is provided. In one embodiment, a photovoltaic device includes a transparent conductive oxide (TCO) layer deposited over the substrate, and a plurality of electrical conductive paths disposed in electrical contact with the TCO layer, wherein the plurality of electrical conductive paths extend discontinuously across opposing sides of the substrate.

### BACKGROUND OF THE INVENTION

1. Field of the Invention

Embodiments of the present invention generally relate to solar cells and methods for forming the same. More particularly, embodiments of the present invention relate to the formation of discontinuous gridlines on, beneath or within a transparent conducting oxide (TCO) layer to obtain tunable module voltage and current for thin film photovoltaic devices.

2. Description of the Related Art

Solar cells convert solar radiation and other light into usable electrical energy. The energy conversion occurs as the result of the photovoltaic effect. Solar cells may be formed from crystalline material or from amorphous or micro-crystalline materials. Generally, there are two major types of solar cells that are produced in large quantities today, which are crystalline silicon solar cells and thin film solar cells. Crystalline silicon solar cells typically use either mono-crystalline substrates (i.e., single-crystal substrates of pure silicon) or a multi-crystalline silicon substrates (i.e., poly-crystalline or polysilicon).

Typically, thin film solar cells include active regions, or photoelectric conversion units, and a transparent conductive oxide (TCO) film disposed as a front electrode and/or as a back electrode. The photoelectric conversion unit includes a p-type silicon layer, an n-type silicon layer, and an intrinsic type (i-type) silicon layer sandwiched between the p-type and n-type silicon layers. Typical thin film solar cells may have one or more p-i-n junctions. When the p-i-n junction of the solar cell is exposed to sunlight (consisting of energy from photons), the sunlight is converted to electricity through the PV effect.

Usually, a single sheet solar cell alone does not have a sufficient output voltage for a PV module. It is thus often necessary to use multiple individual solar cells connected nearly in series and tiled into larger solar arrays to increase the power and voltage. The number of cells in series determines the module operating voltage. In a new thin film tandem junction module design there have been developed more than 100 individual solar cells connected in series to obtain a practical operating power output over 600 volts. However, operators working under such a high power output will require a special protection and therefore, increases the average solar cell cost.

In order to obtain an increased power output while reducing the operating voltage, one of the easiest ways is to use less but wider solar cells in series connection. Wider cell width will generally improve the module power output and efficiency due to the increased active solar cell area. However, an increased cell width will also decrease overall performance since the series resistance from the front TCO layer is increased accordingly. Meanwhile, wider cell widths also result in severe electrical losses in contact layers due to increasing cell current.

Therefore, there is a need for an improved method for obtaining an increased power output while reducing the operating voltage with wider solar cells for thin film solar cells.

### SUMMARY OF THE INVENTION

Embodiments of the present invention generally provide a solar cell array formed on a substrate, comprising a TCO layer deposited over the substrate, and a plurality of electrical conductive paths disposed in electrical contact with the TCO layer, wherein the plurality of electrical conductive paths extend discontinuously across opposing sides of the substrate.

Embodiments of the present invention also provide a solar cell array formed on a substrate, comprising a substrate having a TCO layer, one or more silicon-containing film stacks, and a back metal layer formed thereon, a plurality of vertical scribing lines, wherein at least two vertical scribing lines are formed in the TCO layer, at least two vertical scribing lines are formed in the silicon-containing film stack, and at least two vertical scribing lines are formed in the back metal layer, and each of the vertical scribing lines are aligned parallel to one another, and a plurality of electrical conductive paths extending discontinuously across opposing sides of the substrate through at least a portion of the TCO layer without intersecting with the vertical scribing lines formed in the TCO layer.

Embodiments of the present invention also provide a method for fabricating a series of solar cell array on a substrate, comprising providing a substrate having a TCO layer formed thereon, forming at least two vertical scribing lines in the TCO layer to isolate the TCO layer into individual cells, providing a plurality of electrical conductive paths electrically in contact within the TCO layer to enhance current conduction of the TCO layer, wherein the plurality of electrical conductive paths are substantially perpendicular to the plurality of scribing lines, and forming a silicon-containing film stack over the TCO layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a plain view of a substrate having a multiplicity of solar cell arrays formed thereon of the prior art;

FIG. 2 depicts a cross-sectional view of a portion of solar cell arrays formed on the substrate cutting along section line 2-2 of FIG. 1;

FIG. 3A depicts a plain view of a plurality of solar cell arrays formed on the substrate having multiple discontinuous gridlines according to one embodiment of the present invention;

FIG. 3B is a close-up plain view of a region of the solar array illustrating one configuration of the scribing lines formed in the various layers disposed on the substrate;

FIG. 3C depicts a cross-sectional view of the substrate taken along line 3C-3C in FIG. 3A;

FIG. 4 illustrates a structure formed using the steps described in conjunction with FIG. 5 with arrows indicating a current flow path “PT”; and

FIG. 5 depicts a flow diagram of a process sequence for fabricating the discontinuous gridlines in accordance with one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments

### DETAILED DESCRIPTION

Embodiments of the present invention relate to the formation of discontinuous gridlines on, beneath or within a transparent conducting oxide (TCO) layer to obtain tunable module voltage and current for thin film photovoltaic devices. The discontinuous gridlines advantageously reduces the effective sheet resistivity of the TCO layer while improving the current conduction of the TCO layer, enabling the use of wider cells to decrease active area loss on the light incident surface while reducing operating voltage almost by half and increasing the operating current without loss in efficiency. Wider solar cells also reduce the number of laser scribes lines that would otherwise required to isolate individual cells from each other when formed with the current standard cell width. With different configurations of the gridlines as discussed below, the module voltage and current of the device are tunable to meet any module performance requirements.

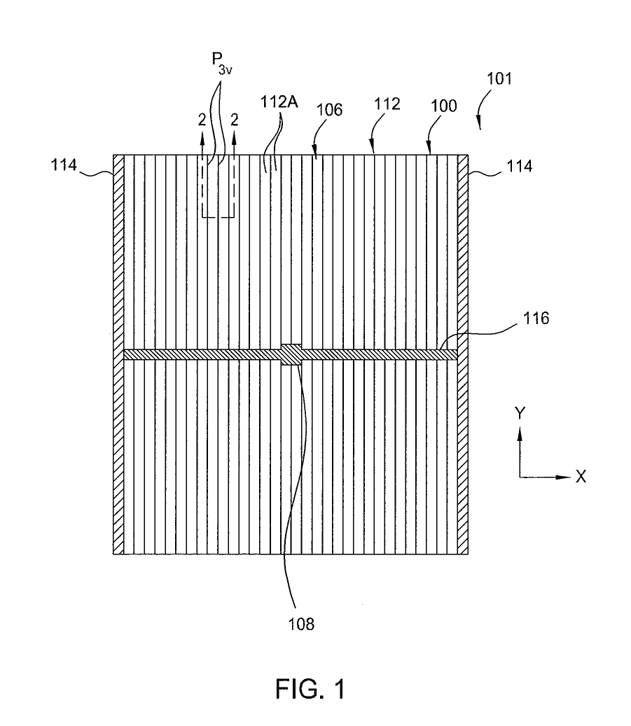

FIG. 1 depicts a plain view of a substrate having a multiplicity of solar cell arrays formed thereon of the prior art. As can be seen, the multiplicity of formed PV solar cells, or solar cells 112A formed on a substrate 100, connected into a solar array 112, which are all electrically connected by a sequence of depositions and scribing lines formed by cutting steps. The multiplicity of solar cells 112A are electrically connected to buss lines 114 that are each located at opposing sides of the solar array 112. A cross-buss 116 is then electrical connected to the buss lines 114 to collect the current and voltage generated therefrom to a junction box 108. In order to form a desired number and patterns of cells on the substrate 100, a plurality of scribing processes may be performed on the material layers formed on the substrate 100 to achieve cell-to-cell and cell-to-edge isolation. For example, the scribing process may be performed to form scribe lines P₁ᵥ, P₂ᵥ, and P₃ᵥ in different material layers of the cells to form isolation groves on the substrate 100. the total area of solar cell modules is divided into cell strips, such as solar cells 112A2, 112A3, which are interconnected by a sequence of depositions and scribing lines formed by cutting steps.

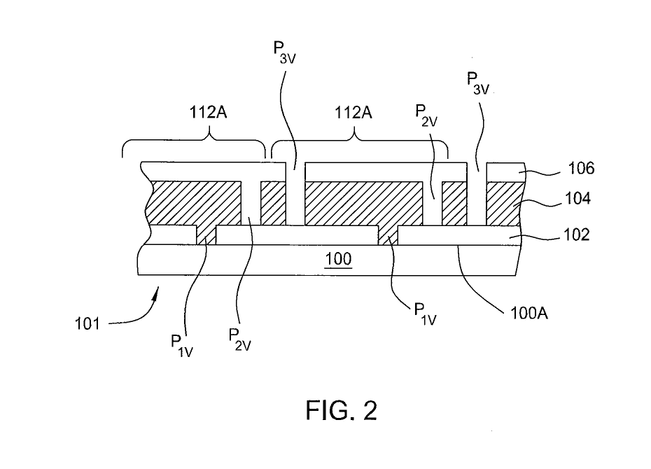

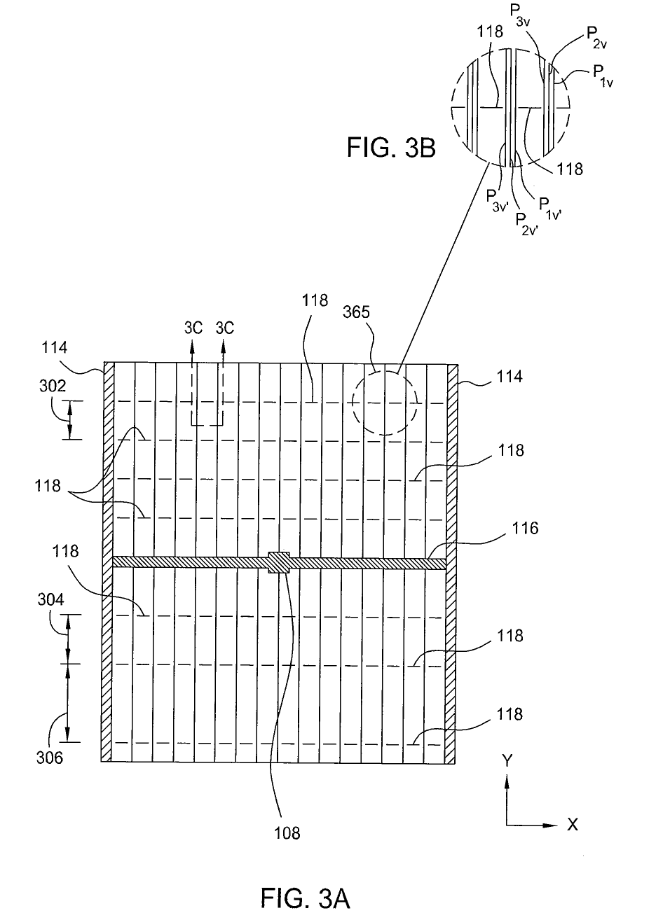

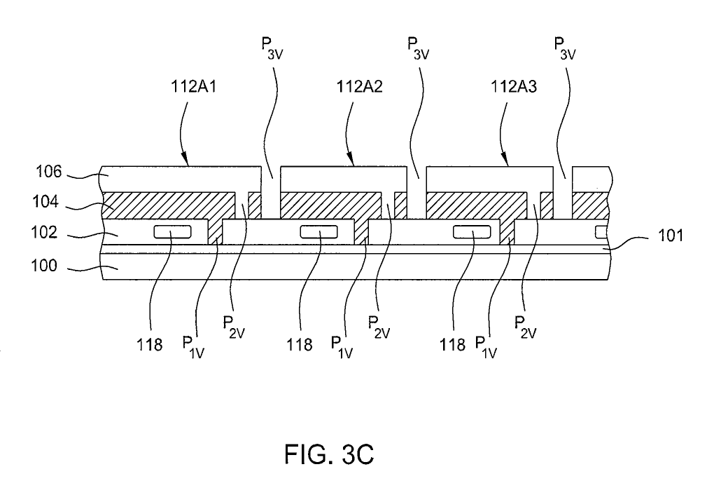

FIG. 2 depicts a cross-sectional view of a portion of solar cell arrays formed on the substrate 100 cutting along section line 2-2 of FIG. 1. It is noted that a P1 scribing process often refers to a scribing process performed in a transparent conductive oxide (TCO) layer 102 disposed on the substrate 100. A P2 scribing process often refers to a scribing process performed in a film stack 104 disposed over the TCO layer 102. A P3 scribing process often refers to a scribing process performed in a back metal layer 106 disposed over the film stack 104. One will note that the scribe lines P₁ᵥ and P₂ᵥ, which are generally offset in a horizontal direction α-direction shown in FIG. 1), are not shown in FIG. 1 for clarity. The scribe lines P₁ᵥ and P₂ᵥ are generally aligned parallel to the scribe line P₃ᵥ and are positioned below the back metal layer 106 (FIG. 2). In the example depicted in FIGS. 1 and 2, a vertical P1 scribing process is performed to form an isolation line P₁ᵥ, in the TCO layer 102. The term “vertical,” as used herein to describe the orientation of the scribing lines, generally includes scribe lines that are aligned in a direction parallel to the Y-direction and perpendicular to the horizontal direction (X-direction), which are shown in FIGS. 1 and 3A. The formed X-Y plane is generally parallel to the surface 100A (FIG. 2) of the substrate 100 on which the material layers are formed. A vertical P2 scribing process is performed to form an isolation line P₂ᵥ in the film stack 104 formed over the TCO layer 102. Furthermore, a vertical P3 process is performed on the back metal layer 106 disposed over the film stack 104 to form the isolation line P₃ᵥ formed through the back metal layer 106 and the film stack 104. As shown in FIG. 2, each scribing line P₁ᵥ, P₂ᵥ, and P₃ᵥ are consecutively and vertically (y-direction) formed in film layers during different stages of the solar cell formation process to form a series of solar cells 112A on the substrate 100. In such a manner, the back metal layer 106 is able to connect through these scribing lines to the front contact (i.e., the TCO layer 102) of the adjacent cells.

In one embodiment, the scribing process used to form scribing lines P₁ᵥ, P₂ᵥ, and P₃ᵥ is a laser scribing process. The laser source may contain an infrared (IR) laser beam source, a Nd:vanadate (Nd:YVO₄) laser beam source, crystalline disk laser source, fiber-diode (fiber laser) or other suitable laser beam sources to ablate materials from the substrate surface to form the above-mentioned scribing lines P₁ᵥ, P₂ᵥ, and P₃ᵥ. In one embodiment, the laser beam source may emit a continuous or pulsed wave of radiation at a wavelength between about 1030 nm and about 1070 nm, such as about 1064 nm that is delivered from either side of the substrate 100. In one example, the laser beam source may emit a continuous or pulsed wave of radiation at a wavelength between about 200 nm and about 2000 nm, such as about 1064 nm that is delivered from either side of the substrate 100. The laser source efficiently removes the materials from the substrate 100 without damage adjacent layers disposed therearound. In one embodiment, the vertical P1 scribing process uses a 1064 nm wavelength pulsed laser to pattern the material disposed on the substrate 100, while the vertical P2 scribing process and vertical P3 scribing process each use a 532 nm wavelength pulsed laser to ablate desired regions of the deposited layers. The use of a 532 nm wavelength laser in the vertical P2 and vertical P3 scribing processes has been found to be useful in preventing damage to the TCO layer. Alternatively, the laser source and/or laser scribing tool utilized to perform the vertical P1, P2 or P3 scribing process in each different layer may be configured the same as needed. Alternatively, a water jet cutting tool, a mechanical polishing tool, a diamond scribe tool, a diamond impregnated belt, grit blasting or a grinding wheel may also be used to mechanically grind, ablate, and isolate the various segments on the substrate 100 of the solar cells arrays as needed.

FIG. 3A depicts a plain view of a plurality of solar cell arrays formed on the substrate 100 having multiple discontinuous gridlines 118 extended between the buss lines 114 according to one embodiment of the present invention. It should be noted that multiple discontinuous gridlines 118 are generally formed on, beneath or within the TCO layer 102. The discontinuous gridlines 118 as shown in FIGS. 3A and 3B are exposed for ease of illustration. FIG. 3B is a close-up plain view of a region 365 of the solar array 112 illustrating one configuration of the scribing lines P₁ᵥ, P₂ᵥ, and P₃ᵥ formed in the various layers disposed on the substrate 100. It is noted that each line shown in FIG. 3A actually represents three laser scribes (FIG. 3B). The vertical scribing lines P₁ᵥ, P₂ᵥ, and P₃ᵥ may be formed within the material layers disposed on the substrate 100 to isolate the solar cells 112A and/or regions within the formed solar cells 112A. As discussed above with referenced to FIG. 2, P₁ᵥ line refers to a vertical scribing line (y-direction) formed on the TCO layer 102 disposed on the substrate 100. P₂ᵥ line refers to a vertical scribing line (y-direction) formed on the film stack 104 disposed over the TCO layer 102, while the P₃ᵥ line refers to a vertical scribing line (y-direction) formed within the back metal layer 106 which is disposed over the film stack 104. FIG. 3C depicts a cross-sectional view of the substrate 100 taken along line 3C-3C in FIG. 3A.

Referring to FIG. 3C, the solar cell typically includes a transparent substrate 100, a TCO layer 102, a film stack 104 having one or more p-i-n junctions, and a metal back layer 106. Three laser scribing steps may be performed to produce trenches or vertical scribing lines P₁ᵥ, P₂ᵥ, and P₃ᵥ, which are generally required to form a high efficiency solar cell device. Although formed together on the substrate 100, the individual cells 112A1, 112A2, and 112A3 are isolated from each other by the scribing lines P₃ᵥ formed in the metal back layer 106 and the film stack 104. In addition, the scribing lines P₂ᵥ is formed in the film stack 104 so that the metal back layer 106 is in electrical contact with the TCO layer 102.

The TCO layer 102 may comprise, for example, tin oxide, zinc oxide, indium tin oxide, cadmium stannate, combinations thereof, or other suitable materials. It is understood that the TCO materials may alsci additionally include dopants and other components. For example, zinc oxide may further include dopants, such as tin, aluminum, gallium, boron, and other suitable dopants. In one aspect, zinc oxide may include 5 atomic % or less of dopants, and more preferably comprises 2.5 atomic % or less aluminum. In certain instances, the substrate 100 may be provided by the glass manufacturers with the TCO layer 102 already deposited thereon. To improve light absorption by enhancing light trapping, the substrate 100 and/or one or more of thin films formed may be optionally textured by wet, plasma, ion, and/or mechanical texturing process. For example, the TCO layer 102 may be textured (not shown) so that the topography of the surface is substantially transferred to the subsequent thin films deposited thereafter.

Optionally, a barrier layer 101 may be formed on the surface of the substrate 100 prior to the deposition of the TCO layer 102 to maintain and provide a consistent contact surface for the TCO layer 102 to be formed thereon. The substrate surface often has contaminants, impurities, or surface adhesives that may impact on the nucleation of the grains when forming the TCO layer 102 thereon. It is believed that the barrier layer 101 as formed between the substrate 100 and the TCO layer 102 may assist preventing impurities from the substrate 100 from diffusing into the TCO layer 102 or other adjacent layers used for forming the junction cells. In addition, these contaminants may also influence on the grain growth and lattice growth orientation of the TCO layer 102, thereby resulting in poor crystalline structure formed in the TCO layer 102 and further reducing electrical and optical properties of the TCO layer 102. It is believed that barrier layer 101 as formed between the substrate 100 and the TCO layer 102 may assist preventing impurities from the substrate 100 from diffusing into the TCO layer 102 or other adjacent layers used for forming the junction cells. In one embodiment, the barrier layer 101 as formed may efficiently prevent the sodium (Na) element from the substrate 100, if any, forming diffusing into the TCO layer 102 so as to preserve a high film quality and purity of the TCO layer 102.

In one embodiment, the barrier layer 101 may be fabricated by aluminum oxide (Al₂O₃), titanium oxide (TiO₂), silicon oxide (SiO₂), zirconium oxide (ZrO₂), hydrogenated silicon nitride (SiNₓH_{y}), carbon doped silicon oxide (SiOC), the combination of silicon oxide (SiO2) and titanium oxide (TiO₂), the combination of silicon oxide (SiO₂) and zirconium oxide (ZrO₂), or any combinations thereof. The barrier layer 101 may be deposited by any suitable deposition techniques, such as CVD, PVD, plating, epi, spaying coating or the like. An example of an exemplary barrier layer 101 is further disclosed in detail in U.S. Patent Application Ser. No. 61/251,995 (Attorney Docket No. APPM/14449), entitled “A BARRIER LAYER DISPOSED BETWEEN A SUBSTRATE AND A TRANSPARENT CONDUCTING OXIDE LAYER FOR THIN FILM SILICON SOLAR CELLS”, filed on Oct. 15, 2009, which is incorporated herein by reference in its entirety.

A film stack 104 is generally deposited on the TCO layer 102 or on the barrier layer 101, if desired. Although not shown in detail, the film stack 104 may be a single p-i-n junction comprising a p-type silicon containing layer (not shown), an intrinsic type silicon containing layer (not shown) formed over the p-type silicon containing layer, and an n-type silicon containing layer (not shown) formed over the intrinsic type silicon containing layer. The p-i-n junction comprises the intrinsic layer to capture a large portion of the solar radiation spectrum. In certain embodiments, the p-type silicon containing layer is a p-type amorphous or microcrystalline silicon layer. In one example, the p-type amorphous silicon layer may be formed to a thickness between about 60 Å and about 300 Å. In one embodiment, the intrinsic type silicon containing layer is an intrinsic type amorphous silicon layer having a thickness between 1,500 Å and about 3,500 Å. In certain embodiments, the intrinsic type silicon containing layer is an intrinsic type amorphous and microcrystalline mixed silicon layer having a thickness between about 500 Å and about 2 μm. In certain embodiments, the n-type silicon containing layer is a n-type microcrystalline silicon layer having a thickness between about 100 Å and about 400 Å. During the photovoltaic process, solar radiation is primarily absorbed by the intrinsic layers of the p-i-n junction and is converted to electron-holes pairs. The electric field created between the p-type layer and the n-type layer that extends across the intrinsic layer causes electrons to flow toward the n-type layers and holes to flow toward the p-type layers creating a current.

In addition to the single junction design as described here, it is contemplated that the film stack 104 may be a tandem junction module having a first p-i-n junction and a second p-i-n junction formed thereon. When a tandem junction module is desired, the second p-i-n junction may have a p-type silicon containing layer, an intrinsic type silicon containing layer, and a n-type silicon containing layer. The p-type silicon containing layer, intrinsic type silicon containing layer and the n-type silicon containing layer formed in the second p-i-n junction may be deposited in the same or similar manner as p-type silicon containing layer, intrinsic type silicon containing layer and the n-type silicon containing layer formed in the first p-i-n junction. For example, in one embodiment the second p-i-n junction may comprise a p-type microcrystalline silicon layer, an intrinsic type microcrystalline silicon layer formed over the p-type microcrystalline silicon layer, and an n-type amorphous silicon layer formed over the intrinsic type microcrystalline silicon layer. In certain embodiments, the p-type microcrystalline silicon layer may be formed to a thickness between about 100 Å and about 400 Å. In certain embodiments, the intrinsic type microcrystalline silicon layer may be formed to a thickness between about 10,000 Å and about 30,000 Å. In certain embodiments, the n-type amorphous silicon layer may be formed to a thickness between about 100 Å and about 500 Å. A tandem junction module solar cell which has two p-i-n junctions with different band gap can generate more electric power than a single junction design, because it generates electric power using both shorter and longer wavelength light, at the top wide gap amorphous silicon layer and bottom narrow gap microcrystalline silicon layer, respectively. This type of solar cell is generally desired as it expected to achieve higher conversion efficiency.

The metal back layer 106 as illustrated in FIG. 3C may include, but not limited to a material selected from the group consisting of Al, Ag, Ti, Cr, Au, Cu, Pt, alloys thereof, and combinations thereof. It is contemplated that other films, materials, substrates, and/or packaging may be provided over metal back layer 106 to complete the solar cell device. The formed solar cells may be interconnected to form modules, which in turn can be connected to form arrays, as discussed previously.

In the embodiment shown in FIGS. 3A and 3C, a plurality of electrically conducting materials are embedded into the TCO layer 102 in the form of gridlines 118 to enhance the current conduction of the TCO layer 102. The gridlines 118 should be narrow but thick and highly conductive metal lines with a low contact resistance to silicon-containing film stack 104. A suitable material for the gridlines 118 may include, but not limited to Ag, Cu, Au, Al, an alloy or compound thereof. As will be discussed below, the gridlines 118 may be deposited on the barrier layer 101, on the TCO layer 102, or any other suitable manner to form within the TCO layer 102 in a pattern consisting of one or more layers or strips forming a network pattern. As illustrated in FIG. 3A, each of the gridlines 118 generally runs perpendicular to scribing lines P₁ᵥ, P₂ᵥ, and P₃ᵥ formed in the TCO layer 102, the film stack 104, and the back metal layer 106, respectively, in a broken or discontinuous manner extending across opposing sides of the substrate 100, that is, discontinuously extending between two buss lines 114. When viewing closely, each of the gridlines 118 is extended between at least two sets of scribing lines, e.g., between at least first set of first scribing lines P₁ᵥ, P₂ᵥ, P₃ᵥ and a second set of scribing lines P₁ᵥ′, P₂ᵥ′, P₃ᵥ′ that is immediately adjacent to the first scribing lines P₁ᵥ, P₂ᵥ, P₃ᵥ, without intersecting with the first and second set of scribing lines, as shown in FIG. 3B. In one embodiment, the discontinuous gridlines 118 are arranged in a spaced apart and parallel relationship to one another. In one aspect, the spacing 302 (FIG. 3A) between at least two adjacent, parallel gridlines 118 is about 20 μm to about 2000 μm. One of ordinary skill in the art will note that other patterns of gridlines 118 may be used. For example, the discontinuous gridlines 118 may be arranged in straight lines, triangular lattices, hexagonal lattices, sinusoidal patterns, or any arbitrary arrangements, depending upon temperature variation across the substrate or film properties as discussed below.

The discontinuous gridlines 118 may be a sub-wavelength in size (e.g., height and width) and thus provide small or no optical obscuration of the photons striking the formed solar cell substrate. The formed gridlines 118 can even be narrower than the optical wavelength, so that light blocking is greatly reduced. In one embodiment, the gridlines 118 may be formed on the order of about 10 μm to about 300 μm wide. In another embodiment, the gridlines 118 may be formed on the order of about 200 μm to about 250 μm wide. In addition, the gridlines 118 may be formed on the order of about 1 μm to about 10 μm thick. In one embodiment, the gridlines 118 is formed on the order of about 0.3 μm to about 5 μm thick. In the embodiment where the gridlines is about 2-5 μm thick, the single junction module might be less favorable since the gridline having such a thickness may shunt the modules due to the device thickness of the single junction. However, a skill artisan in the art will appreciate that the width or thickness of the gridline 118 and the type of junction module may vary upon application without affecting the device performance or conversion efficiency.

The discontinuous gridlines 118 may be formed within the TCO layer 102 by any suitable techniques. Alternatively, the discontinuous gridlines 118 may be formed adjacent to and in electrical contact with the TCO layer 102 to achieve the similar effect of enhancing the current conduction of the TCO layer 102. For example, the discontinuous gridlines may be deposited on the barrier layer 101 prior to deposition of the TCO layer 102, or on the TCO layer 102 by screen printing or ink-jet printing process.

It has been observed that with discontinuous gridlines 118 arranged in accordance with the embodiments as described above, the resistance of the TCO layer 102 is greatly reduced and thus improving current conduction of the TCO layer 102. This is because the TCO layer such as indium tin oxide, indium oxide, zinc oxide, or tin oxide are typically not efficient current collectors due to their inherent resistivity. High sheet resistance causes ohmic losses in the TCO layer that decreases the overall conversion efficiency of the device. By incorporating these discontinuous gridlines 118 into the TCO layer 102, the effective sheet resistivity of the TCO layer 102 is found to be significantly reduced, which in turn allows for the use of wider cells to decrease active area loss on the light incident surface without an increase in the resistance loss due to the area of the interconnection structure. It has been proved that the use of wider cells contributes to about 30% reduction in the ablative capacity of the laser that would otherwise required to isolate individual cells from each other when formed with the current standard cell width. Therefore, the overall performance is increased.

Due to the use of wider cells, the total number of the solar cells has been reduced from about, for example, 106 series connected cells to about 70 series connected cells having a wider cell width, resulting in increased operating current without loss in efficiency while decreasing the operating voltage almost by half. In one example, the open-circuit voltage Voc has been reduced from about 142 Volts to about 94 Volts while short-circuit current Isc has been increased from about 1.22 A to about 1.83 A. Therefore, the module voltage and current of the device are tunable to meet any module performance requirements. The embodiments as described above have been proved to offer a better module efficiency loss lower than 7% with a wider cell width as compared to the current standard baseline of 1 cm cell width.

It is critical that the active area loss is minimized as it has a direct impact on module power output and efficiency. A wider cell will decrease active area loss because the loss contribution from the scribe area is decreased (since the scribe area does not contribute to photocurrent). However, if the cell width is increased, the series resistance from the front TCO layer increases accordingly, thereby reducing overall performance. Moreover, a wider cell width will also result in severe electrical losses in contact layers due to increasing cell current. Therefore, albeit the integrated gridlines in the TCO layer help reduce its sheet resistance, optimization of the cell width must consider both area losses due to patterning and series resistance losses caused by the TCO sheet resistance in order to obtain a minimum efficiency loss associated with the active area loss and ohmic loss. In addition, the total width of the gridlines needs to be carefully determined because of the shadowing effect they have on the solar cell, inasmuch as these gridlines are generally opaque. Compromise between transparency and series resistance have led the present inventors to determine a minimized loss in module efficiency for a cell with a 2 cm width when the gridlines is about 2 μm thick and about 250 μm wide. In one another embodiment, the loss in module efficiency is minimized for a cell with a 3 cm width when the gridlines is about 5 μm thick and about 200 μm wide. In yet another preferable embodiment, the loss in module efficiency is minimized for a cell with a 1.5 cm width when the gridlines is about 2 μm thick and about 200 μm wide.

Nom Referring again to FIG. 3A, the distance of each gridlines 118 formed within the TCO layer 102 (or adjacent to the TCO layer 102 in alternative embodiments) may be spaced and positioned in accordance with different film profiles or thickness formed at different locations of the substrate to reduce current accumulation and evenly distribute the generated current passing through in different region of the cell. Typically, the gridlines 118 are arranged in a spaced apart and parallel relationship to one another as discussed previously, and the spacing 302 between at least two adjacent, parallel gridlines 118 may vary ranging between about 20 μm to about 2000 μm. In some embodiments, it may be desirable to vary the spacing of the discontinuous gridlines 118 to compensate for the variation in temperature across the substrate 100 when the formed solar cell device is placed into use. Temperature variation across the substrate 100 during the generation of current by the solar cell device may occur due to presence of heat sinks and/or regions that generate a higher amount of heat found on or within the formed solar cell device. Therefore, by adjusting the spacing between the gridlines 118, the amount of heat generated (i.e., related to current flow) and operating temperature of each region of the solar cell can be controlled and optimized. In one embodiment, the spacing between adjacent gridlines is not constant, but rather is configured with a various density to compensate for variations in film properties or solar cell configurational differences. For example, the spacing between at least two adjacent, parallel gridlines 118 as shown in FIG. 3A may be wider (e.g., spacing 306) or narrower (e.g., spacing 304) than the spacing 302 in view of different film profile, film thickness, substrate dimension, material characteristics, or the amount of heat generated etc., thereby enabling “floating” gridlines within or adjacent to the TCO layer. It is to be understood that the spacings 302, 304, 306 are exemplary and may be ranging from about 20 μm to about 2000 μm, or outside this range if desired.

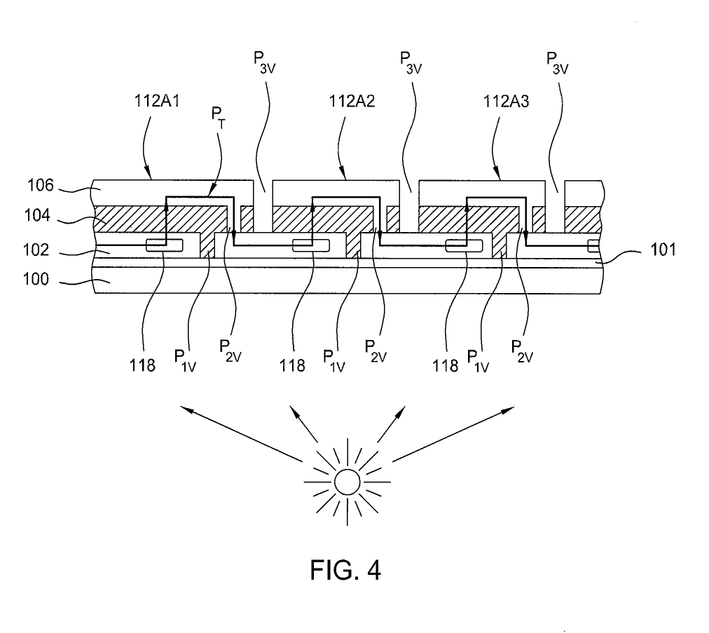

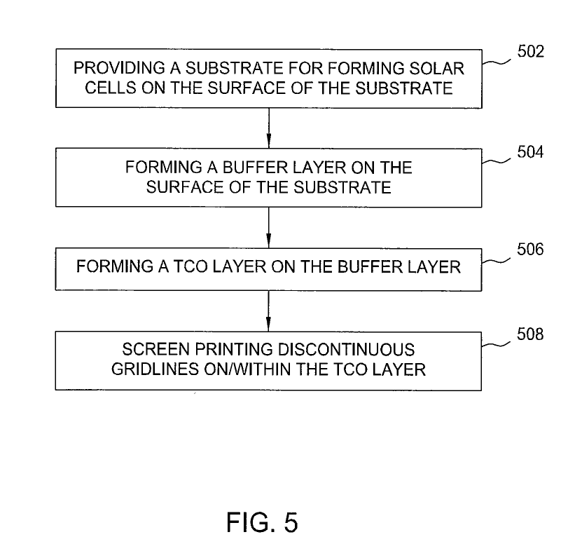

FIG. 4 illustrates a structure formed using the steps described below in conjunction with FIG. 5 for series-connection in thin film silicon solar cell modules with arrows indicating a current flow path “PT”. As discussed previously, the total area of solar cell modules is divided into cell strips, such as solar cells 112A₁, 112A₂, and 112A₃ as shown, which are interconnected by a sequence of depositions and scribing lines formed by laser cutting steps. In one embodiment, after deposition of TCO onto the substrate, the front contact (i.e., the TCO layer 102) is cut into strips with a width between about 0.5 cm and 3 cm. The scribing lines P₂ᵥ prepared into the film stack 104 on top of the TCO layer 102 directly next to the TCO scribing line P₁ᵥ allows for a connection between the front contact (i.e., the TCO layer 102) and the back contact (i.e., the back metal layer 106). Therefore, the back contact of one cell, for example, 112A₁, is electrically connected to the front contact of the adjacent cell, for example, 112A₂, through the scribing lines P₂, in the film stack 104. As shown in FIG. 4, the current flow path “PT” in general is created and flowed between the adjacent solar cells 112A₁, 112A₂, and 112A₃ from the back metal layer 106 of the solar cell 112A₁, through the scribing line P₂ᵥ in the film stack 104 of the solar cell 112A₂, to the TCO layer 102 and the discontinuous gridline 118 of the solar cell 112A₂. The current flow “PT” then pass through the film stack 104 of the solar cell 112A₂ to the back metal layer 106 of the solar cell 112A₃, thereby interconnecting the solar cells 112A₁, 112A₂, 112A₃, and neighboring solar cells (not shown) in series in the solar array 112. Although not shown here, it is contemplated that the solar cells 112A₁, 112A₂, 112A₃, and neighboring solar cells (not shown) may be interconnected in series as well in various embodiments where the discontinuous gridlines 118 are formed adjacent to the TCO layer 102, i.e., above or beneath the TCO layer 102.

FIG. 5 depicts a flow diagram of a process sequence for fabricating the discontinuous gridlines 118 in accordance with one embodiment of the present invention. The process starts at step 502 by providing the substrate 100 into a processing chamber, such as a sputter process chamber available from Applied Materials, Inc., located in Santa Clara, Calif. The substrate 100 may be utilized to form a single, tandem, or multiple junction solar cells as described above with referenced to FIGS. 2 and 3C. In one embodiment, the substrate 100 is a glass substrate, a polymer substrate, or any suitable transparent substrate that allows sunlight to pass therethrough.

At step 504, after the substrate 100 is transferred into the processing chamber, a process gas mixture is supplied into the sputter process chamber to bombard the source material from the target and reacts with the sputtered material to form a barrier layer 101 (optional) with desired film properties on the substrate surface. In the embodiment where the first target is configured as a silicon target, the process gas mixture supplied into the processing chamber may contain nitrogen gas, oxygen gas and optional an inert gas, such as He or Ar. The nitrogen gas and the oxygen gas supplied into the processing region react with the silicon material dislodged from the target, forming a silicon oxynitride (SiON) as the barrier layer 101 on the substrate surface. If desired, the amount of nitrogen gas supplied into the processing chamber may be controlled less than the amount of oxygen gas supplied thereto so as to form the barrier layer 101 as an oxygen rich SiON layer, which may promote growth of the TCO layer 102 subsequently formed thereon. In such a case, after sputtering process is performed to deposit the barrier layer 101 on the substrate 100, the RF bombardment to the target may be temporarily ceased to remain only plasma on the processing chamber to allow a surface treatment process being performed on the barrier layer 101 formed on the substrate surface. The surface treatment process may be performed to treat the surface of the barrier layer 101 as an oxygen rich surface, thereby promoting grain growth and nucleation of the TCO layer 102. In this configuration, the barrier layer 101 may be in form of any silicon containing layer, including SiN, SiON, SiO₂, so that the oxygen rich surface may be obtained by performing the oxygen surface treatment process as discussed.

At step 506, after the optional barrier layer 101 is formed on the substrate 100, a process gas mixture is supplied into the sputter process chamber. The process gas mixture supplied into the sputter process chamber bombards the source material from the target and reacts with the sputtered material to form the desired TCO layer 102 on the barrier layer 101. In one embodiment, the gas mixture may include reactive gas, non-reactive gas, and the like. Examples of non-reactive gas include, but not limited to, inert gas, such as Ar, He, Xe, and Kr, or other suitable gases. Examples of reactive gas include, but not limited to, O₂, N₂, N₂O, NO₂, H₂, NH₃, H₂O, among others. Non-reactive gases may be supplied when the sputtering process is an RF, DC or AC sputtering process in which the sputtering target comprises the TCO material to be deposited such as ZnO. When the sputtering process is a reactive sputtering process, the sputtering target may comprise the metal for the TCO, such as zinc, which reacts with the reactive gas to deposit ZnO on the substrate.

In one embodiment, the argon (Ar) gas may be supplied into the sputter process chamber to assist in bombarding the target to sputter materials from the target surface. The sputtered materials from the target react with the reactive gas in the sputter process chamber, thereby forming a TCO layer having desired film properties on the substrate. The gas mixture and/or other process parameters may be varied during the sputtering deposition process, thereby creating the TCO layer with desired film properties for different film quality requirements.

In one particular embodiment, the process gas mixture supplied into the sputter process chamber includes at least one of Ar, O₂ or H₂. In one embodiment, the O₂ gas may be supplied at a flow rate between about 0 sccm and about 100 sccm, such as between about 5 sccm and about 30 sccm, for example between about 5 sccm and about 15 sccm. The Ar gas may be supplied into the processing chamber at a flow rate between about 150 sccm and between 500 sccm. The H₂ gas may be supplied into the processing chamber 100 at a flow rate between about 0 sccm and between 100 sccm, such as between about 5 sccm and about 30 sccm. Alternatively, O₂ gas flow may be controlled at a flow rate per total flow rate below about 0.1 percent of the total gas flow rate. H₂ gas flow may be controlled at a flow rate per total flow rate below about 0.1 percent of the total gas flow rate.

After forming the TCO layer 102 on the substrate 100, an optional surface treatment process, such as a wet etching, dry etching or surface texturing process, may be performed to roughen the surface of the TCO layer 102. It is believed that the TCO layer 102 having a certain degree of surface roughness may assist trapping lights in the TCO layer 102 for a longer time and scattering light to the junction cells subsequently formed thereon. Accordingly, the optional surface treatment process, or surface roughening process may be performed on the TCO layer 102 to form a roughened surface on the surface of the TCO layer 102. In one embodiment the surface roughness process may be performed by a wet etching process by using a batch cleaning process in which the TCO layer 102 on the substrate 100 is exposed to a cleaning solution. The TCO layer 102 may be textured using a wet cleaning process in which they are sprayed, flooded, or immersed in a cleaning solution. The clean solution may be an SC1 cleaning solution, an SC2 cleaning solution, HF-last type cleaning solution, diluted HCl containing solution, ozonated water solution, hydrofluoric acid (HF) and hydrogen peroxide (H₂O₂) solution, or other suitable and cost effective cleaning solution. The wet etching process may be performed on the substrate 100 between about 5 seconds and about 600 seconds, such as about 30 seconds to about 240 second, for example about 120 seconds.

At step 508, after the TCO layer 102 (with appropriate vertical scribing lines to separate the layer into cells) is formed on the substrate 100, the substrate 100 may be transferred into another processing chamber to deposit discontinuous gridlines 118 on the TCO layer 102. The discontinuous gridlines 118 may be screen printed through a printing mask with holes finer than the normal resolution of the screen printing process. After the paste (i.e., the gridlines) is applied, the screen is removed leaving a pattern of paste upon the TCO layer in a spaced apart and parallel relationship to one another, running perpendicular to scribing lines P₁ᵥ, P₂ᵥ, and P₃ᵥ formed in the TCO layer 102, the film stack 104, and the back metal layer 106, respectively, in a broken or discontinuous manner extending across opposing sides of the substrate 100. Thereafter, the paste is dried in a drying chamber at an appropriate temperature such that the paste is cured and adhered to the TCO layer 102. In one embodiment, each of the formed discontinuous gridlines 118 is extended between at least two sets of scribing lines, e.g., between at least one set of first scribing lines P₁ᵥ, P₂ᵥ, P₃ᵥ and a second set of scribing lines P₁ᵥ, P₂ᵥ, P₃ᵥ that is immediately adjacent to the first scribing lines P₁ᵥ, P₂ᵥ, P₃ᵥ, without intersecting with the first and second set of scribing lines P₁ᵥ, P₂ᵥ, and P₃ᵥ. In one embodiment, the spacing between at least two adjacent, parallel gridlines 118 is ranging between about 20 μm to about 2000 μm.

The amount of printed paste depends on the thickness of the screen material and the emulsion and the open area of the fabric forming the screen. It also depends on the printed line width, which is this case, may be on the order of about 200 μm to about 250 μm wide and about 0.3 μm to about 5 μm thick. Nevertheless, it is understood that the discontinuous gridlines 118 should be arranged in a manner to provide only small or no optical obscuration of the photons striking the formed solar cell substrate, minimizing the shadowing effect resulting from these gridlines.

It is contemplated that the gridlines of the present invention may be formed in many different ways such as ink-jet printing, CVD, PVD, or texture etching process. For example, in one embodiment the surface of the TCO layer 102 may be textured by use of techniques that are well known in the art, such as etch process, to form a plurality of pyramidal type structures (e.g., tetrahedrons) having peaks and valleys. Thereafter, an electrically conductive metal may be formed in the valleys by sputtering, plating, or other suitable techniques between the tetrahedrons, thereby forming a micro-pattern of discontinuous gridlines. In yet another embodiment, the TCO layer 102 may have a desired pattern of discontinuous grooves formed therein by suitable techniques known in the art and then filled with electrical conducting materials such as conducting epoxies, silver inks, conducting polymers, metals including Ag, Cu, Au, Al, and others, thereby forming a pattern of gridlines extending discontinuously across opposing sides of the substrate without intersecting with scribing lines P₁ᵥ, P₂ᵥ, and P₃ᵥ.

In one another embodiment, the discontinuous gridlines 118 may be ink-jet printed or screen printed on the surface of the barrier layer prior to deposition of the TCO layer 102 to achieve the similar effect of enhancing the current conduction of the TCO layer 102. Alternatively, the discontinuous gridlines 118 may be embedded/formed within the TCO layer 102 in various manners through suitable techniques. For example, the embedded discontinuous gridlines 118 may be formed by performing a first step sputtering to deposit a first portion of the TCO layer, followed by the screen-printing of the gridlines on the first portion of the TCO layer, and then performing a second step of sputtering to deposit the second portion of the TCO layer on top of the gridlines. Although not discussed here, it is contemplated that the process conditions and/or parameters during the sputter deposition may vary as necessary upon application.

Thus, methods for forming a discontinuous gridlines within a TCO layer for fabricating solar cell devices are provided. The discontinuous gridlines advantageously reduces the effective sheet resistivity of the TCO layer while improving the current conduction of the TCO layer, enabling the use of wider cells to decrease active area loss on the light incident surface while reducing operating voltage and increasing the operating current without loss in efficiency. Wider solar cells also reduce the number of laser scribes lines that would otherwise required to isolate individual cells from each other when formed with the current standard cell width, resulting in about 30% reduction in the ablative capacity of the laser. With different configurations of the gridlines, the module voltage and current of the device are tunable to meet any module performance requirements.

While the foregoing is directed to embodiments of the present invention, other and further embodiments of the invention may be devised without departing from the basic scope thereof, and the scope thereof is determined by the claims that follow.

What is claimed is:

1. A solar cell array formed on a substrate, comprising:
a transparent conductive oxide (TCO) layer deposited over the substrate; and
a plurality of electrical conductive paths disposed in electrical contact with the TCO layer, wherein the plurality of electrical conductive paths extend discontinuously across opposing sides of the substrate.

2. The solar cell array of claim 1, wherein the plurality of electrical conductive paths are deposited on a surface of the TCO layer, within the TCO layer, or below the TCO layer.

3. The solar cell array of claim 2, wherein the plurality of electrical conductive paths are in a pattern consisting of one or more layers or strips forming a network pattern.

4. The solar cell array of claim 1, further comprising:
a silicon-containing film stack formed over the TCO layer.

5. The solar cell array of claim 4, wherein each of the plurality of electrical conductive paths generally runs perpendicular to vertical scribing lines formed in the TCO layer and the silicon-containing film stack without intersecting therewith.

6. The solar cell array of claim 1, wherein each of the plurality of electrical conductive paths are arranged in a spaced apart relationship to one another.

7. The solar cell array of claim 6, wherein a spacing between at least two adjacent electrical conductive paths is ranging between about 20 μm to about 2000 μm.

8. The solar cell array of claim 7, wherein each of the plurality of electrical conductive paths is about 10 μm to about 300 μm wide and about 0.3 μm to about 5 μm thick.

9. The solar cell array of claim 7, wherein a distance between at least two adjacent vertical scribing lines in the TCO layer is about 0.5 cm to about 3 cm.

10. The solar cell array of claim 2, wherein the plurality of the electrical conductive paths are formed by screen printing process, ink-jet printing process, CVD process, PVD process, texture etching process, or the like.

11. The solar cell array of claim 1, wherein the plurality of electrical conductive path include a material selected from a group consisting of copper (Cu), silver (Ag), tin (Sn), cobalt (Co), rhenium (Rh), nickel (Ni), zinc (Zn), lead (Pb), aluminum (Al), alloys thereof, and combinations thereof.

12. The solar cell array of claim 1, further comprising:
a barrier layer disposed between the TCO layer and the substrate, wherein the barrier layer comprises a dielectric material selected from the group consisting of silicon nitride, silicon oxynitride, silicon oxide and combinations thereof.

13. A solar cell array formed on a substrate, comprising:
a substrate having a TCO layer, one or more silicon-containing film stacks, and a back metal layer formed thereon;
a plurality of vertical scribing lines, wherein at least two vertical scribing lines are formed in the TCO layer, at least two vertical scribing lines are formed in the silicon-containing film stack, and at least two vertical scribing lines are formed in the back metal layer, and each of the vertical scribing lines are aligned parallel to one another; and
a plurality of electrical conductive paths extending discontinuously across opposing sides of the substrate through at least a portion of the TCO layer without intersecting with the vertical scribing lines formed in the TCO layer.

14. The solar cell array of claim 13, wherein the plurality of electrical conductive paths are arranged in a spaced apart relationship to each other and are substantially perpendicular to the plurality of scribing lines.

15. The solar cell array of claim 14, wherein a spacing between at least two adjacent electrical conductive paths is ranging between about 20 μm to about 200 μm.

16. The solar cell array of claim 14, wherein each of the plurality of electrical conductive paths is about 0.3 μm to about 5 μm thick and about 200 μm to about 250 μm wide.

17. The solar cell array of claim 16, wherein a distance between at least two adjacent vertical scribing lines formed in the TCO layer is about 0.5 cm to about 3 cm.

18. A method for fabricating a series of solar cell array on a substrate, comprising:
providing a substrate having a TCO layer formed thereon;
forming at least two vertical scribing lines in the TCO layer to isolate the TCO layer into individual cells;
providing a plurality of electrical conductive paths electrically in contact within the TCO layer to enhance current conduction of the TCO layer, wherein the plurality of electrical conductive paths are substantially perpendicular to the plurality of scribing lines; and
forming a silicon-containing film stack over the TCO layer.

19. The method of claim 18, wherein the plurality of the electrical conductive paths are arranged in a spaced apart relationship to each other.

20. The method of claim 18, wherein the plurality of electrical conductive paths extend between opposing sides of the substrate through at least a portion of the TCO layer without intersecting with the vertical scribing lines formed in the TCO layer.

21. The method of claim 19, wherein the spacing between at least two adjacent electrical conductive paths is about 20 μm to about 200 μm.

22. The method of claim 18, wherein a distance between at least two adjacent scribing lines formed in the TCO layer is about 0.5 cm to about 3 cm.

23. The solar cell array of claim 22, wherein each of the plurality of electrical conductive paths is about 200 μm to about 250 μm wide and about 0.3 μm to about 5 μm thick.
